(19) United States
(12) Patent Application Publication
(10) Pub. No.: US 2023/0411145 A1
(43) Pub. Date: Dec. 21, 2023

(54) PROCESSING METHOD, METHOD OF MANUFACTURING SEMICONDUCTOR DEVICE, PROCESSING APPARATUS AND NON-TRANSITORY COMPUTER-READABLE RECORDING MEDIUM

(71) Applicant: Kokusai Electric Corporation, Tokyo (JP)

(72) Inventors: Yusaku OKAJIMA, Toyama-shi (JP); Hiroki Hatta, Toyama-shi (JP); Yoshinori Imai, Toyama-shi (JP)

(73) Assignee: Kokusai Electric Corporation, Tokyo (JP)

(21) Appl. No.: 18/459,558

(22) Filed: Sep. 1, 2023

Related U.S. Application Data
(63) Continuation of application No. PCT/JP22/08551, filed on Mar. 1, 2022.

(30) Foreign Application Priority Data
Mar. 17, 2021 (JP) 2021-044119

(51) Int. Cl. H01L 21/02

(52) U.S. Cl. CPC H01L 21/02271; H01L 21/02211; H01L 21/0217

(57) ABSTRACT

According to the present disclosure, the step coverage performance of the film can be improved on the substrate. According to one embodiment of the present disclosure, there is provided a technique that includes: forming a film on a substrate provided with a concave structure on a surface thereof by performing a cycle a predetermined number of times, wherein the cycle includes: (a) supplying a source gas to the substrate from a side of the substrate; and (b) supplying a reactive gas to the substrate, and wherein, in (a), by colliding the source gas with an inner wall of the concave structure, the source gas is decomposed to generate an intermediate substance and the intermediate substance adheres to the inner wall of the concave structure, and wherein, in (b), the intermediate substance adhered to the inner wall of the concave structure reacts with the reactive gas.

### CROSS-REFERENCE TO RELATED PATENT APPLICATION

This application is a bypass continuation application of PCT International Application No. PCT/JP2022/008551, filed on Mar. 1, 2022, in the WIPO, the international application being based upon and claiming the benefit of priority from Japanese Patent Application No. 2021-044119, filed on Mar. 17, 2021, in the Japanese Patent Office, the entire contents of which are hereby incorporated by reference.

### BACKGROUND

### 1. Field

The present disclosure relates to a processing method, a method of manufacturing a semiconductor device, a processing apparatus and a non-transitory computer-readable recording medium.

### 2. Related Art

According to some related arts, as a part of a manufacturing process of a semiconductor device, by supplying an inert gas or a hydrogen-containing gas toward a substrate together with a source gas, a technique capable of setting a flow velocity of the source gas flowing in a direction parallel to a surface of the substrate to be greater than a flow velocity of the inert gas flowing in the direction parallel to the surface of the substrate in a step of purging an inside of a process vessel is disclosed.

In recent years, an aspect ratio of a concave structure (or a recess) such as a groove formed on the substrate may increase in accordance with a reduction of a cell area due to a miniaturization of a device such as the semiconductor device, and it is preferable to improve a step coverage performance, for example, when a film is formed on the substrate provided with a deeper concave structure. In order to improve the step coverage performance, it is preferable to sufficiently supply a gas such as the source gas to a lower portion of the concave structure. However, when trying to sufficiently supply the gas to the lower portion of the concave structure for coping with an increase in the aspect ratio, an upper portion of the device may be supplied with an excessive amount of a process gas such as the source gas, and the step coverage performance may not be improved. Further, in order to improve the step coverage performance, while sufficiently supplying the gas to the lower portion of the concave structure, it is preferable to suppress a supply amount of the process gas to the upper portion of the device.

### SUMMARY

According to the present disclosure, there is provided a technique capable of improving a step coverage performance of a film formed on a substrate.

According to one embodiment of the present disclosure, there is provided a technique that includes: forming a film on a substrate provided with a concave structure on a surface thereof by performing a cycle a predetermined number of times, wherein the cycle includes: (a) supplying a source gas to the substrate from a side of the substrate; and (b) supplying a reactive gas to the substrate, and wherein, in (a), by colliding the source gas with an inner wall of the concave structure, the source gas is decomposed to generate an intermediate substance and the intermediate substance adheres to the inner wall of the concave structure, and wherein, in (b), the intermediate substance adhered to the inner wall of the concave structure reacts with the reactive gas.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2 is a diagram specifically illustrating a vertical cross-section of a substrate support shown in FIG. 1.

FIG. 3A is a diagram schematically illustrating a first gas supplier according to the embodiments of the present disclosure, FIG. 3B is a diagram schematically illustrating a second gas supplier according to the embodiments of the present disclosure and FIG. 3C is a diagram schematically illustrating a third gas supplier according to the embodiments of the present disclosure.

FIGS. 4A through 4C are diagrams schematically illustrating examples of a chemical structural formula of a first gas according to the embodiments of the present disclosure.

FIG. 5A is a diagram schematically illustrating a process chamber exhauster according to the embodiments of the present disclosure and FIG. 5B is a diagram schematically illustrating a transfer chamber exhauster according to the embodiments of the present disclosure.

FIG. 6 is a block diagram schematically illustrating a configuration of a controller and related components of the substrate processing apparatus according to the embodiments of the present disclosure.

FIG. 7 is a diagram schematically illustrating a substrate processing sequence according to the embodiments of the present disclosure.

FIG. 8 is a diagram schematically illustrating a state of a surface of a substrate when the first gas is supplied according to the embodiments of the present disclosure.

FIG. 9 is a diagram schematically illustrating a relationship between a supply time of the first gas and a decomposition amount of the first gas according to the embodiments of the present disclosure.

### DETAILED DESCRIPTION

<Embodiments of Present Disclosure>

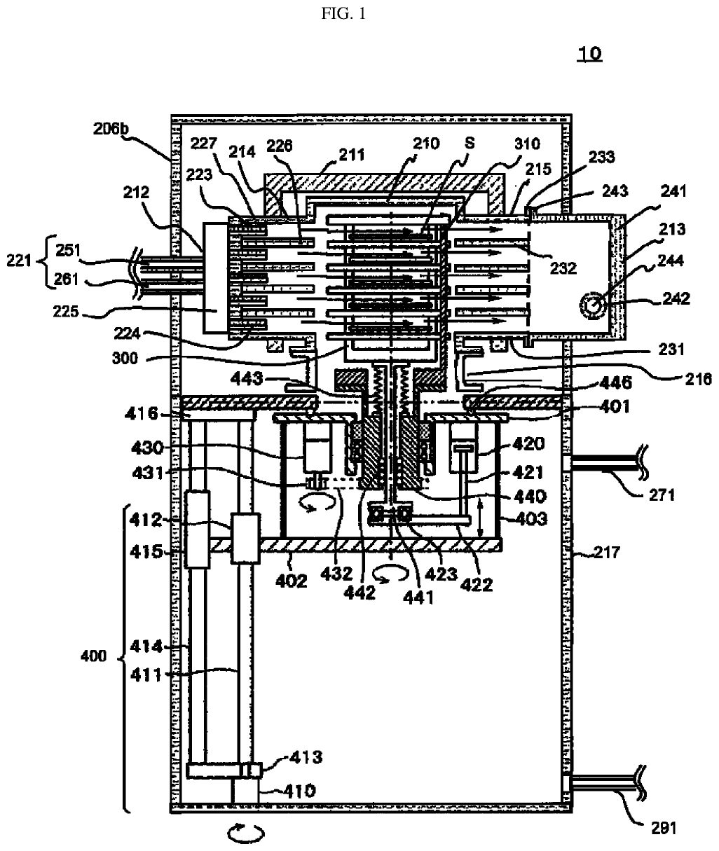

Hereinafter, one or more embodiments (also simply referred to as “embodiments”) according to the technique of the present disclosure will be described with reference to FIGS. 1 through 7. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

(1) Configuration of Substrate Processing Apparatus

A configuration of a substrate processing apparatus 10 according to the present embodiments will be described mainly with reference to FIG. 1.

The substrate processing apparatus 10 includes a reaction tube storage chamber 206. In the reaction tube storage chamber 206, a reaction tube 210 of a cylindrical shape extending in a vertical direction, a heater 211 serving as a heating structure (furnace body) installed on an outer periphery of the reaction tube 210, a gas supply structure 212 serving as a part of a gas supplier (which is a gas supply system), and a gas exhaust structure 213 serving as a part of a gas exhauster (which is a gas exhaust system) are provided. The gas supplier may further include an upstream side gas guide 214 or nozzles 223 and 224, which will be described later. Further, the gas exhauster may further include a downstream side gas guide 215, which will be described later.

The gas supply structure 212 is provided upstream in a gas flow direction in the reaction tube 210, and a gas such as a source gas and a reactive gas is supplied into the reaction tube 210 through the gas supply structure 212. Then, the gas is supplied to a substrate S in a horizontal direction. The gas exhaust structure 213 is provided downstream in the gas flow direction in the reaction tube 210, and the gas in the reaction tube 210 is discharged (exhausted) through the gas exhaust structure 213. The gas supply structure 212, an inner portion of the reaction tube 210 and the gas exhaust structure 213 communicate with one another in the horizontal direction.

On an upstream side of the reaction tube 210 between the reaction tube 210 and the gas supply structure 212, the upstream side gas guide 214 configured to adjust a flow of the gas supplied through the gas supply structure 212 is provided. Further, on a downstream side of the reaction tube 210 between the reaction tube 210 and the gas exhaust structure 213, the downstream side gas guide 215 configured to adjust the flow of the gas discharged from the reaction tube 210 is provided. A lower end of the reaction tube 210 is supported by a manifold 216.

The reaction tube 210, the upstream side gas guide 214 and the downstream side gas guide 215 are implemented as a continuous structure. For example, each of the reaction tube 210, the upstream side gas guide 214 and the downstream side gas guide 215 is made of a material such as quartz and silicon carbide (SiC). Further, each of the reaction tube 210, the upstream side gas guide 214 and the downstream side gas guide 215 is constituted by a heat transmittable structure capable of transmitting a heat radiated from the heater 211. The heat of the heater 211 can heat the substrate S and the gas.

The gas supply structure 212 is connected to each of a gas supply pipe 251 and a gas supply pipe 261, and includes a distribution structure 225 configured to distribute the gas supplied through each gas supply pipe described above. A plurality of nozzles including the nozzle 223 and a plurality of nozzles including the nozzle 224 are provided at a downstream side of the distribution structure 225. Hereafter, the plurality of nozzles including the nozzle 223 may also be simply referred to as “nozzles 223”, and the plurality of nozzles including the nozzle 224 may also be simply referred to as “nozzles 224”. As described later, it is possible to supply different types of gases through the gas supply pipe 251 and the gas supply pipe 261, respectively. The nozzle 223 and the nozzle 224 are arranged up and down in the vertical direction or side by side in the horizontal direction. In the present embodiments, the gas supply pipe 251 and the gas supply pipe 261 may also be collectively or individually referred to as a “gas supply pipe 221”. Each of the nozzles 223 and 224 may also be referred to as a gas ejection structure.

The distribution structure 225 is configured such that each gas can be supplied to the nozzles 223 through the gas supply pipe 251 and to the nozzles 224 through the gas supply pipe 261. For example, a gas flow path can be provided for each combination of the gas supply pipe and the nozzle corresponding to the gas supply pipe. Thereby, since the gases supplied through the gas supply pipes described above are not mixed, it is possible to suppress a generation of particles that may be generated when the gases are mixed in the distribution structure 225.

The upstream side gas guide 214 includes a housing 227 and a partition plate 226. The partition plate 226 extends in the horizontal direction. The “horizontal direction” of the partition plate 226 may refer to a direction toward a side wall of the housing 227. A plurality of partition plates including the partition plate 226 are arranged in the vertical direction. Hereafter, the plurality of partition plates including the partition plate 226 may also be simply referred to as partition plates 226. The partition plate 226 is fixed to the side wall of the housing 227 such that it is possible to prevent the gas from flowing into an adjacent region below or above the partition plate 226. By preventing the gas from flowing into the adjacent region, it is possible to reliably form a gas flow described later.

The partition plate 226 is a continuous structure extending in the horizontal direction and provided with no hole. The partition plates 226 are provided at positions corresponding to a plurality of substrates including the substrate S, respectively. Hereafter, the plurality of substrates including the substrate S may also be simply referred to as substrates S. The nozzle 223 and the nozzle 224 are arranged between adjacent partition plates 226 or between the partition plate 226 and the housing 227.

The flow of the gas ejected through the nozzle 223 or the nozzle 224 is adjusted by the partition plate 226, and then the gas whose flow is adjusted is supplied to a surface of the substrate S. That is, when viewed from the substrate S, the gas is supplied along a lateral direction of the substrate S. Since the partition plate 226 extends in the horizontal direction and is a continuous structure without a hole, a mainstream of the gas is restrained from being moved in the vertical direction and is moved in the horizontal direction. Therefore, a pressure loss of the gas reaching each substrate S can be uniformized over the vertical direction.

The downstream side gas guide 215 is configured such that a ceiling thereof is provided above an uppermost substrate among the substrates S supported by a substrate support structure 300 described later, and a bottom thereof is provided below a lowermost substrate among the substrates S supported by the substrate support structure 300.

The downstream side gas guide 215 includes a housing 231 and a partition plate 232. The partition plate 232 extends in the horizontal direction. The “horizontal direction” of the partition plate 232 may refer to a direction toward a side wall of the housing 231. Further, a plurality of partition plates including the partition plate 232 are arranged in the vertical direction. Hereafter, the plurality of partition plates including the partition plate 232 may also be simply referred to as partition plates 232. The partition plate 232 is fixed to the side wall of the housing 231 such that it is possible to prevent the gas from flowing into an adjacent region below or above the partition plate 232. By preventing the gas from flowing into the adjacent region, it is possible to reliably form the gas flow described later. A flange 233 is provided on a portion of the housing 231 that comes into contact with the gas exhaust structure 213.

The partition plate 232 is a continuous structure extending in the horizontal direction and provided without a hole. The partition plates 232 are provided at positions corresponding to the substrates S and corresponding to the partition plates 226, respectively. It is preferable that the partition plate 226 and the partition plate 232 corresponding to the partition plate 226 are provided at the same height. Further, when processing the substrate S, it is preferable that the substrate S, the partition plate 226 corresponding to the substrate S and the partition plate 232 corresponding to the partition plate 226 are provided at the same height. With such a structure, the gas flow in the horizontal direction passing over the partition plate 226, the substrate S and the partition plate 232 is formed by the gas supplied through each nozzle, as shown by each arrow in the drawing. By configuring the partition plate 232 as described above, it is possible to uniformize the pressure loss of the gas ejected (or discharged) through each of the substrates S. Therefore, the flow of the gas passing through each of the substrates S is formed in the horizontal direction toward the gas exhaust structure 213 while suppressing a gas flow in the vertical direction.

By providing the partition plates 226 and the partition plates 232, it is possible to uniformize the pressure loss in the vertical direction at both an upstream and a downstream of each of the substrates S. As a result, it is possible to reliably form a horizontal gas flow in which the flow along the vertical direction is suppressed over the partition plate 226, the substrate S and the partition plate 232.

The gas exhaust structure 213 is provided downstream of the downstream side gas guide 215. The gas exhaust structure 213 is constituted mainly by a housing 241 and a gas exhaust pipe connection structure 242. A flange 243 is provided on a portion of the housing 241 adjacent to the downstream side gas guide 215. Since the gas exhaust structure 213 is made of a metal and the downstream side gas guide 215 is made of quartz, the flange 233 and the flange 243 are fixed to each other with a fixing structure such as a screw via a cushioning material such as an O-ring. It is preferable that the flange 243 is arranged outside the heater 211 such that an influence of the heater 211 on the O-ring can be suppressed.

The gas exhaust structure 213 communicates with a space of the downstream side gas guide 215. The upper ends of the housing 231 and the housing 241 form a structure with a continuous height. That is, a height of a ceiling of the housing 231 is configured to be the same as that of a ceiling of the housing 241, and a height of a bottom of the housing 231 is configured to be the same as that of a bottom of the housing 241. An exhaust hole 244 is provided at a downstream side of the housing 241 on a lower portion of the housing 241 or in the horizontal direction. The gas exhaust structure 213 is provided in a lateral direction of the reaction tube 210, and is a lateral exhaust structure configured to exhaust the gas along the lateral direction of the substrate S.

The gas that has passed through the downstream side gas guide 215 is exhausted through the exhaust hole 244. When the gas is exhausted through the exhaust hole 244, since the gas exhaust structure 213 is not provided with a structure similar to the partition plate described above, the gas flow whose vertical component is non-zero is formed toward the exhaust hole 244.

A transfer chamber 217 is installed in a lower portion of the reaction tube 210 via the manifold 216. In the transfer chamber 217, the substrate S may be transferred to (or placed on) the substrate support structure (hereinafter, may also be simply referred to as a “boat”) 300 by a vacuum transfer robot via a substrate loading/unloading port, or the substrate S may be transferred (or taken) out of the substrate support structure 300 by the vacuum transfer robot.

Inside the transfer chamber 217, the substrate support structure 300, a partition plate support 310, and a vertical driver structure (vertical driver) 400 constituting a first driving structure (first driver) configured to drive the substrate support structure 300 and the partition plate support 310 (hereinafter, also collectively referred to as a “substrate retainer”) in the vertical direction and a rotational direction can be stored. FIG. 1 shows a state in which the substrate support structure 300 is elevated by the vertical driving structure 400 and stored in the reaction tube 210.

The vertical driving structure 400 constituting the first driving structure may include: as drive sources, a vertical driving motor 410; a rotational driving motor 430; and a boat vertical driving structure 420 provided with a linear actuator serving as a substrate support elevator capable of driving the substrate support structure 300 in the vertical direction.

By rotationally driving a ball screw 411, the vertical driving motor 410 serving as a partition plate support elevator moves a nut 412 screwed with respect to the ball screw 411 in the vertical direction along the ball screw 411. As a result, the partition plate support 310 and the substrate support structure 300 are driven in the vertical direction between the reaction tube 210 and the transfer chamber 217 together with a base plate 402 fixing the nut 412. The base plate 402 is also fixed to a ball guide 415 that is engaged with a guide shaft 414, and is configured to be capable of being smoothly moved in the vertical direction along the guide shaft 414. An upper end portion and a lower end portion of each of the guide shaft 414 and the ball screw 411 are fixed to a fixing plate 416 and a fixing plate 413, respectively.

The rotational driving motor 430 and the boat vertical driving structure 420 provided with the linear actuator constitute a second driving structure, and are fixed to a base flange 401 serving as a lid supported by a side plate 403 on the base plate 402.

The rotational driving motor 430 is configured to drive a rotation transmission belt 432 that engages with a tooth structure 431 attached to a front end (tip) thereof, and is configured to rotationally drive a support 440 that engages with the rotation transmission belt 432. The support 440 is configured to support the partition plate support 310 by a base structure 311, and is configured to rotate the partition plate support 310 and the substrate support structure 300 by being driven by the rotational driving motor 430 via the rotation transmission belt 432.

The boat vertical driving structure 420 provided with the linear actuator is configured to drive a shaft 421 in the vertical direction. A plate 422 is attached to a front end (tip) of the shaft 421. The plate 422 is connected to a support 441 fixed to a base structure 301 of the substrate support structure 300 via a bearing 423. By connecting the support 441 to the plate 422 via the bearing 423, when the partition plate support 310 is rotationally driven by the rotational driving motor 430, it is possible to rotate the substrate support structure 300 together with the partition plate support 310.

On the other hand, the support 441 is supported by the support 440 via a linear guide bearing 442. With such a configuration, when the shaft 421 is driven in the vertical direction by the boat vertical driving structure 420 provided with the linear actuator, it is possible to drive the support 441 fixed to the substrate support structure 300 in the vertical direction relative to the support 440 fixed to the partition plate support 310.

The support 440 fixed to the partition plate support 310 and the support 441 fixed to the substrate support structure 300 are connected by a vacuum bellows 443.

An O-ring 446 for a vacuum seal is installed on an upper surface of the base flange 401 serving as the lid, and as shown in FIG. 1, by driving the vertical driving motor 410 such that the upper surface of the base flange 401 is elevated to a position where it is pressed against the transfer chamber 217, it is possible to maintain an inside of the reaction tube 210 airtight.

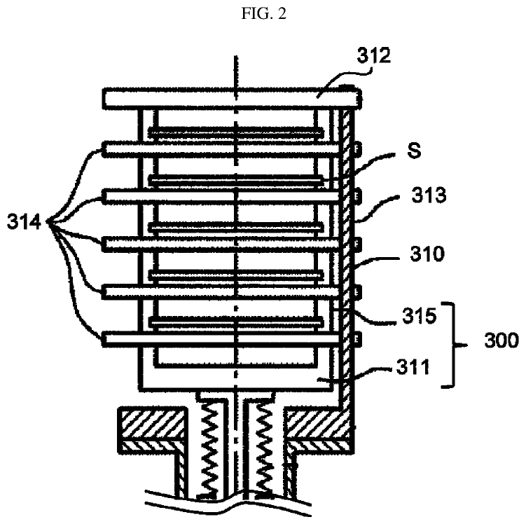

Subsequently, a substrate support will be described in detail with reference to FIGS. 1 and 2. The substrate support is constituted at least by the substrate support structure 300 configured to support the substrate S, and is accommodated in the reaction tube 210. The substrates S are arranged directly below an inner wall of a top plate of the reaction tube 210. Further, the substrate support is configured such that a process of transferring or replacing the substrate S by the vacuum transfer robot in the transfer chamber 217 via a substrate loading/unloading port (not shown) can be performed and a process of loading the transferred (or replaced) substrate S into the reaction tube 210 such that a film-forming step of forming a film on the surface of the substrate S can be performed. For example, the substrate loading/unloading port is provided on a side wall of the transfer chamber 217. Further, the substrate support may further include the partition plate support 310.

A plurality of partition plates including a partition plate 314 of a disk shape are fixed to the partition plate support 310 at a predetermined pitch therebetween at a support column 313 supported between the base structure 311 and a top plate 312. Hereafter, the plurality of partition plates including the partition plate 314 may also be simply referred to as “partition plates 314”. The substrate support structure 300 includes a configuration in which a plurality of support rods 315 are supported on the base structure 311 and the substrates S are supported by the plurality of support rods 315 at a predetermined interval therebetween.

The substrates S are placed on the substrate support structure 300 at the predetermined interval therebetween by the plurality of support rods 315 supported by the base structure 311. Spaces between adjacent substrates S supported by the plurality of support rods 315 are partitioned by the partition plate 314 (which are of a disk shape) fixed (or supported) at the predetermined interval (pitch) to the support column 313 supported by the partition plate support 310. According to the present embodiments, the partition plate 314 is arranged directly below the substrate S. The partition plates 314 may be provided above or below their adjacent substrates S. Alternatively, the partition plates 314 may be provided above and below their adjacent substrates S. The partition plates 314 are configured to separate the spaces between adjacent substrates S from one another.

The predetermined interval between the substrates S placed on the substrate support structure 300 is the same as a vertical interval (that is, the pitch described above) of the partition plates 314 fixed to the partition plate support 310. Further, a diameter of the partition plate 314 is set to be larger than a diameter of the substrate S.

The substrate support structure 300 is configured to support a plurality of substrates (for example, 5 substrates) as the substrates S in a multistage manner in the vertical direction by the plurality of support rods 315. Each of the base structure 311, the partition plate 314 and the plurality of support rods 315 is made of a material such as quartz and silicon carbide (SiC). Further, the present embodiments will be described by way of an example in which 5 substrates are supported by the substrate support structure 300 as the substrates S. However, the present embodiments are not limited thereto. For example, the substrate support structure 300 may be configured to support about 5 substrates to 50 substrates as the substrates S. Further, the partition plate 314 of the partition plate support 310 may also be referred to as a “separator”.

The partition plate support 310 and the substrate support structure 300 are driven by the vertical driving structure 400 in the vertical direction between the reaction tube 210 and the transfer chamber 217 and in the rotational direction around a center of the substrate S supported by the substrate support structure 300.

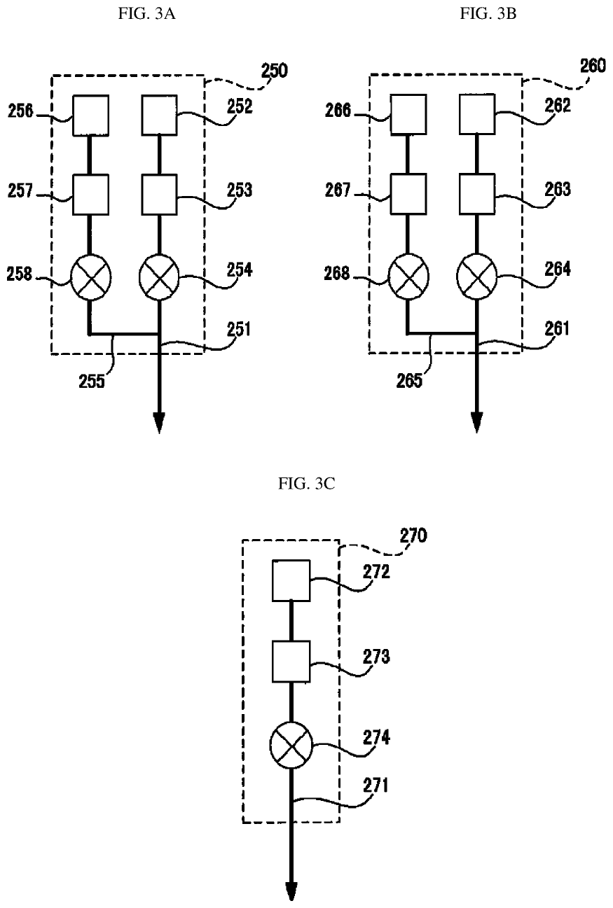

Subsequently, the gas supplier will be described in detail with reference to FIGS. 3A though 3C. As shown in FIG. 3A, a first gas supply source 252, a mass flow controller (MFC) 253 serving as a flow rate controller (a flow rate control structure) and a valve 254 serving as an opening/closing valve are sequentially installed at the gas supply pipe 251 in this order from an upstream side to a downstream side of the gas supply pipe 251.

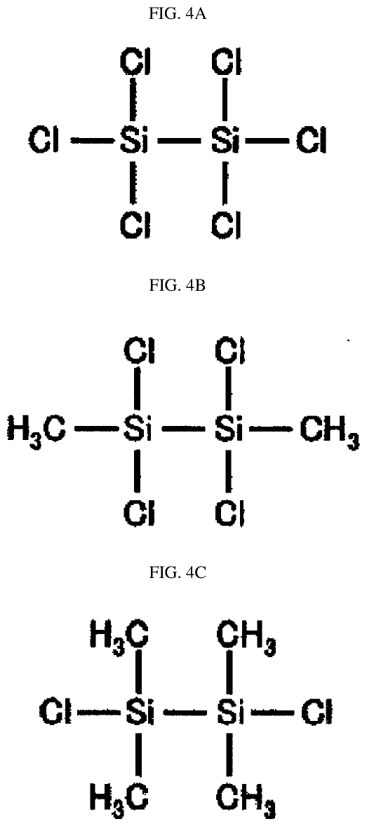

The first gas supply source 252 is a source of a first gas containing a first element (also referred to as a “first element-containing gas”). The first gas serves as the source gas, that is, one of process gases. According to the present embodiments, at least two silicon (Si) atoms are bonded in a single molecule of the first gas, and for example, refers to a gas containing silicon and chlorine (Cl). For example, the first gas may refer to a gas containing a silicon-silicon (Si—Si) bond such as disilicon hexachloride (Si₂Cl₆, hexachlorodisilane, abbreviated as HCDS) gas shown in FIG. 4A. As shown in FIG. 4A, the HCDS gas contains silicon and a chloro group (chloride) in its chemical structural formula (in one molecule).

The Si—Si bond contains enough energy to be decomposed by a collision with a wall constituting a concave structure (or a recess) of the substrate S, which will be described later, in the reaction tube 210. According to the present embodiments, the term “decomposed” means that the Si—Si bond is broken. That is, the Si—Si bond is broken by the collision with the wall.

A first gas supplier (which is a first gas supply structure or a first gas supply system) 250 is constituted mainly by the gas supply pipe 251, the MFC 253 and the valve 254. The first gas supplier 250 may also be referred to as a “silicon-containing gas supplier” which is a silicon-containing gas supply structure or a silicon-containing gas supply system.

A gas supply pipe 255 is connected to a downstream side of the valve 254 of the gas supply pipe 251. An inert gas supply source 256, an MFC 257 and a valve 258 serving as an opening/closing valve are sequentially installed at the gas supply pipe 255 in this order from an upstream side to a downstream side of the gas supply pipe 255. An inert gas (for example, nitrogen (N₂) gas) is supplied from the inert gas supply source 272.

A first inert gas supplier (which is a first inert gas supply structure or a first inert gas supply system) is constituted mainly by the gas supply pipe 255, the MFC 257 and the valve 258. The inert gas supplied from the inert gas supply source 256 acts as a purge gas for purging the gas remaining in the reaction tube 210 when performing a substrate processing described later. The first gas supplier 250 may further include the first inert gas supplier.

While the present embodiments will be described by way of an example in which the HCDS gas is used as the first gas, the first gas is not limited thereto. For example, a gas containing silicon and a Si—Si bond may be used as the first gas. That is, for example, a gas such as 1,1,2,2-tetrachloro-1,2-dimethyldisilane ((CH₃)₂Si₂Cl₄, abbreviated as TCDMDS) and 1,2-dichloro-1,1,2,2-tetramethyldisilane ((CH₃)₄Si₂Cl₂, abbreviated as DCTMDS) may be used as the first gas. As shown in FIG. 4B, the TCDMDS contains a Si—Si bond, and further contains a chloro group and an alkylene group. Further, as shown in FIG. 4C, the DCTMDS contains a Si—Si bond, and further contains a chloro group and an alkylene group.

As shown in FIG. 3B, a second gas supply source 262, a mass flow controller (MFC) 263 serving as a flow rate controller (a flow rate control structure) and a valve 264 serving as an opening/closing valve are sequentially installed at the gas supply pipe 261 in this order from an upstream side to a downstream side of the gas supply pipe 261.

The second gas supply source 262 is a source of a second gas containing a second element (also referred to as a “second element-containing gas”). The second gas is a gas different from the first gas, and serves as one of the process gases. Further, the second gas may serve as the reactive gas or a modification gas.

According to the present embodiments, the second gas contains the second element different from the first element of the first gas. For example, the second element may be one of oxygen (O), nitrogen (N) and carbon (C). According to the present embodiments, for example, the second gas is a nitrogen-containing gas, and is a hydrogen nitride-based gas containing a nitrogen-hydrogen (N—H) bond such as ammonia (NH₃), diazene (N₂H₂) gas, hydrazine (N₂H₄) gas and N₃H₈ gas.

A second gas supplier (which is a second gas supply structure or a second gas supply system) 260 is constituted mainly by the gas supply pipe 261, the MFC 263 and the valve 264.

A gas supply pipe 265 is connected to a downstream side of the valve 264 of the gas supply pipe 261. An inert gas supply source 266, an MFC 267 and a valve 268 serving as an opening/closing valve are sequentially installed at the gas supply pipe 265 in this order from an upstream side to a downstream side of the gas supply pipe 265. The inert gas (for example, nitrogen (N₂) gas) is supplied from the inert gas supply source 266.

A second inert gas supplier (which is a second inert gas supply structure or a second inert gas supply system) is constituted mainly by the gas supply pipe 265, the MFC 267 and the valve 268. The inert gas supplied from the inert gas supply source 266 acts as the purge gas for purging the gas remaining in the reaction tube 210 when performing the substrate processing described later. The second gas supplier 260 may further include the second inert gas supplier.

As shown in FIG. 3C, a third gas supply source 272, a mass flow controller (MFC) 273 serving as a flow rate controller (a flow rate control structure) and a valve 274 serving as an opening/closing valve are sequentially installed at the gas supply pipe 271 in this order from an upstream side to a downstream side of the gas supply pipe 271. The gas supply pipe 271 is connected to the transfer chamber 217. The inert gas is supplied when the transfer chamber 217 is set to an inert gas atmosphere or when the transfer chamber 217 is exhausted to a vacuum state.

The third gas supply source 272 is a source of the inert gas. A third gas supplier (which is a third gas supply structure or a third gas supply system) 270 is constituted mainly by the gas supply pipe 271, the MFC 273 and the valve 274. The third gas supplier 270 may also be referred to as a “transfer chamber gas supplier” which is a transfer chamber gas supply structure or a transfer chamber gas supply system.

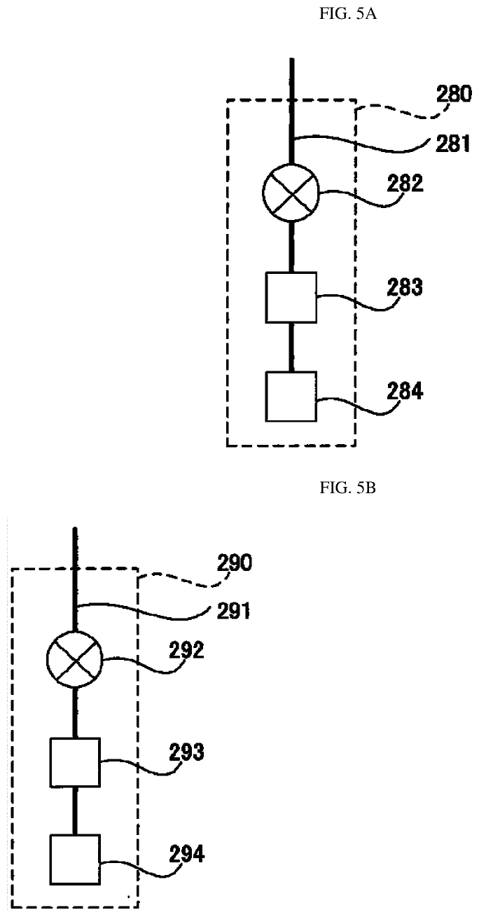

Subsequently, an exhauster (which is an exhaust structure or an exhaust system) will be described with reference to FIGS. 5A and 5B. An exhauster 280 configured to exhaust an inner atmosphere of the reaction tube 210 includes an exhaust pipe 281 that communicates with the reaction tube 210, and is connected to the housing 241 via the gas exhaust pipe connection structure 242.

As shown in FIG. 5A, a vacuum pump 284 serving as a vacuum exhaust apparatus is connected to the exhaust pipe 281 via a valve 282 serving as an opening/closing valve and an APC (Automatic Pressure Controller) valve 283 serving as a pressure regulator (which is a pressure adjusting structure). Thereby, the reaction tube 210 is vacuum-exhausted such that an inner pressure of the reaction tube 210 reaches and is maintained at a predetermined pressure (vacuum degree). The exhaust pipe 281, the valve 282 and the APC valve 283 may also be collectively referred to as the exhauster 280. The exhauster 280 may also be referred to as a “process chamber exhauster”. The exhauster 280 may further include the vacuum pump 284.

An exhauster 290 configured to exhaust an inner atmosphere of the transfer chamber 214 includes an exhaust pipe 291 that is connected to the transfer chamber 214 and that communicates with an inside of the transfer chamber 214.

As shown in FIG. 5B, a vacuum pump 294 serving as a vacuum exhaust apparatus is connected to the exhaust pipe 291 via a valve 292 serving as an opening/closing valve and an APC (Automatic Pressure Controller) valve 293 serving as a pressure regulator (which is a pressure adjusting structure). Thereby, the transfer chamber 214 is vacuum-exhausted such that an inner pressure of the transfer chamber 214 reaches and is maintained at a predetermined pressure (vacuum degree). The exhaust pipe 291, the valve 292 and the APC valve 9 may also be collectively referred to as the exhauster 290. The exhauster 290 may also be referred to as a “transfer chamber exhauster”. The exhauster 290 may further include the vacuum pump 294.

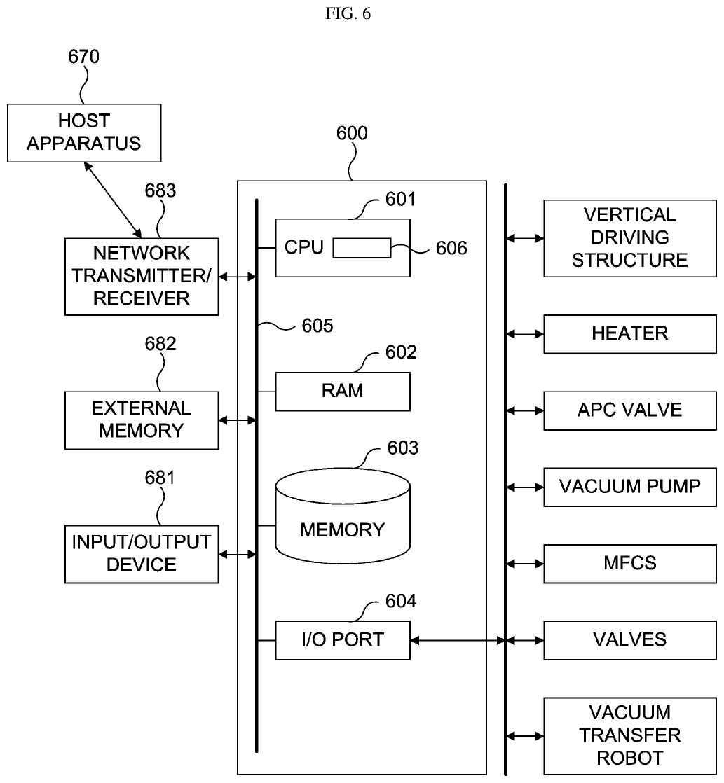

Subsequently, a controller 600 serving as a control structure (control apparatus) will be described with reference to FIG. 6. The substrate processing apparatus 10 includes the controller 600 configured to control operations of components constituting the substrate processing apparatus 10.

FIG. 6 is a diagram schematically illustrating a configuration of the controller 600. The controller 600 may be constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 may exchange data with the CPU 601 via an internal bus 605. The transmission/reception of the data in the substrate processing apparatus 10 may be performed by an instruction from a transmission/reception instruction controller 606, which is also one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule of the substrate S stored in a pod from the host apparatus 670.

For example, the memory 603 may be embodied by a component such as a flash memory and a HDD (Hard Disk Drive). For example, a control program for controlling the operations of the substrate processing apparatus 10 or a process recipe in which information such as sequences and conditions of the substrate processing is stored may be readably stored in the memory 603.

The process recipe is obtained by combining steps of the substrate processing described later, and acts as a program that is executed by the controller 600 to obtain a predetermined result by performing the steps of the substrate processing described later. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 602 serves as a memory area (work area) in which the program or the data read by the CPU 601 are temporarily stored.

The I/O port 604 is electrically connected to the components of the substrate processing apparatus 10 described above.

The CPU 601 is configured to read and execute the control program from the memory 603, and is configured to read the process recipe from the memory 603 in accordance with an instruction such as an operation command inputted from an input/output device 681. The CPU 601 is configured to be capable of controlling the substrate processing apparatus 10 in accordance with contents of the process recipe read from the input/output device 681.

The CPU 601 includes the transmission/reception instruction controller 606. For example, the controller 600 according to the present embodiments may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. Further, a method of providing the program to the computer is not limited to the external memory 682. For example, the program may be directly provided to the computer by a communication interface such as the Internet and a dedicated line instead of the external memory 682. Further, the memory 603 and the external memory 682 may be embodied by a non-transitory computer-readable recording medium. Hereinafter, the memory 603 and the external memory 682 may be collectively or individually referred to as a “recording medium”. In the present specification, the term “recording medium” may refer to the memory 603 alone, may refer to the external memory 682 alone, or may refer to both of the memory 603 and the external memory 682.

Hereinafter, as a part of a manufacturing process of a semiconductor device, the substrate processing will be described by way of an example in which a film-forming process of forming a film on the substrate S is performed by using the substrate processing apparatus 10 described above. In the following description, the controller 600 controls the operations of the components constituting the substrate processing apparatus 10.

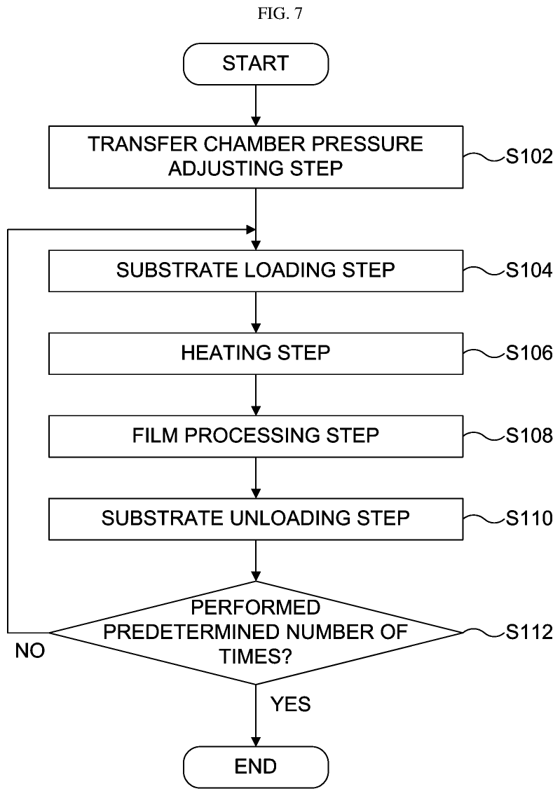

For example, the film-forming process of forming the film on the substrate S by using the first gas and the second gas and by alternately supplying the first gas and the second gas will be described with reference to FIG. 7. A groove serving as the concave structure is formed on the surface of the substrate S.

<S102>

A transfer chamber pressure adjusting step S102 will be described. In the present step, the inner pressure of the transfer chamber 217 is set to the same level as that of a vacuum transfer chamber (not shown) provided adjacent to the transfer chamber 217. Specifically, by operating the exhauster 290, the inner atmosphere of the transfer chamber 217 is exhausted such that the inner atmosphere of the transfer chamber 214 reaches and is maintained at a vacuum level.

<S104>

Subsequently, a substrate loading step S104 will be described. When the inner atmosphere of the transfer chamber 217 reaches and is maintained at the vacuum level, a transfer of the substrate S is started. When the substrate S reaches the vacuum transfer chamber, a gate valve is opened. Then, the substrate S is loaded (transferred) into the transfer chamber 217 by the vacuum transfer robot.

When the substrate S is loaded, the substrate support structure 300 stands by in the transfer chamber 217, and the substrate S is transferred to the substrate support structure 300. When a predetermined number of substrates S are transferred to the substrate support structure 300, the vacuum transfer robot is retracted, and the substrate support structure 300 is elevated by the vertical driving structure 400 to move the substrates S into a process chamber inside the reaction tube 210.

When moving the substrate S to the reaction tube 210, the surface of the substrate S is positioned so as to be aligned with heights of the partition plate 226 and the partition plate 232.

<S106>

Subsequently, a heating step S106 will be described. When the substrate S is loaded into the process chamber inside the reaction tube 210, the inner pressure of the reaction tube 210 is controlled (adjusted) to a predetermined pressure and a surface temperature of the substrate S is controlled to a predetermined temperature. For example, a temperature of the heater 211 is controlled such that a temperature (that is, the surface temperature) of the substrate S reaches and is maintained at a temperature within a range from 100° C. to 1,500° C., preferably from 200° C. to 1,000° C., and more preferably from 400° C. to 800° C. Further, for example, it is conceivable that the inner pressure of the reaction tube 210 reaches and is maintained at a pressure within a range from 5 Pa to 100 kPa.

<S108>

Subsequently, a film processing step S108 will be described. The film processing step S108 is performed after the heating step S06. In the film processing step S108, in accordance with the process recipe, the following steps (that is, a first step, a second step, a third step and a fourth step) are performed a plurality number of times on the substrate S provided with the groove serving as the concave structure on the surface thereof so as to form a predetermined film.

That is, the first gas is supplied into the reaction tube 210 in the first step, the inert gas is supplied into the reaction tube 210 and the inner atmosphere of the reaction tube 210 is exhausted in the second step serving as a purge step, the second gas is supplied into the reaction tube 210 in the third step, and the inert gas is supplied into the reaction tube 210 and the inner atmosphere of the reaction tube 210 is exhausted in the fourth step serving as a purge step. A desired film is formed on the substrate S provided with the groove on the surface thereof by performing a supply process in which the first step through the fourth step are repeatedly and non-simultaneously performed a plurality number of times.

When the gas is supplied, the flow of the gas is formed at the upstream side gas guide 214, a space on the substrate S and the downstream side gas guide 215. Since the gas is supplied to each of the substrates S without the pressure loss on each of the substrates S, it is possible to uniformly perform a processing of the substrates S.

Further, each of the upstream side gas guide 214 and the downstream side gas guide 215 may be configured to correspond to the substrates S. In such a case, it is advantageous in that the number of components can be reduced. However, a pressure between the substrates S or the gas hitting a side surface of the substrate S may cause a turbulent flow, and a gas supply situation changes between the substrates arranged above and below among the substrates S. As a result, variations in the processing may occur between the substrates S. In particular, when the turbulent flow occurs, there is a risk that the gas will stagnate before reaching the substrate S. Then, the gas will be decomposed before reaching the substrate S. As a result, the gas may be deposited on the edge (side) of the substrate S. Thereby, a uniformity of the processing on the surface of the substrate S may be lowered.

As a result, variations may occur in the film processing step. Therefore, providing the upstream side gas guide 214 and the downstream side gas guide 215 corresponding to one substrate S as in the present embodiments is advantageous in reducing the variations in the processing between substrates S.

<First Gas Supply Step: First Step>

The valve 254 is opened so as to supply the first gas into the gas supply pipe 261. The first gas whose flow rate is adjusted by the MFC 253 is supplied into the reaction tube 210 from the gas supply structure 212 via the upstream side gas guide 214. Then, the first gas is exhausted through the space on the substrate S, the downstream side gas guide 215, the gas exhaust structure 213 and the exhaust pipe 281. When supplying the first gas, simultaneously, the valve 258 may be opened so as to supply the inert gas such as the N₂ gas into the gas supply pipe 255. When supplying the first gas, in order to prevent the first gas from entering the gas supply pipe 261, the valve 268 may be opened so as to supply the inert gas into the gas supply pipe 265.

In the present step, for example, the APC valve 283 is appropriately adjusted such that the inner pressure of the reaction tube 210 is set to be a pressure within a range from 1 Pa to 3,990 Pa. For example, a supply flow rate of the first gas controlled (or adjusted) by the MFC 253 is set to be a flow rate within a range from 0.1 slm to 20 slm. In the following, for example, the temperature of the heater 211 is adjusted such that the temperature of the substrate S reaches and is maintained at a temperature within a range from 100° C. to 1,500° C., preferably from 400° C. to 800° C. For example, a supply time (time duration) of supplying the first gas onto the substrate S is set to be a time within a range from 0.1 second to 1,000 seconds. For example, a flow velocity of the first gas is set to be a flow velocity within a range from 0.1 m/second to 100 m/second, preferably from 0.5 m/second to 50 m/second, and more preferably from 1 m/second to 20 m/second. For example, a time for the first gas to reach the substrate S after being ejected from a nozzle outlet is set to be second or less; preferably, 0.0001 second or less; and more preferably, 0.001 second or less.

In the present step, the first gas is supplied to the substrate S in the horizontal direction from a side portion (edge) of the substrate S through the gas supply structure 212 communicating with the process chamber. At least two silicon atoms are bonded (for example, the Si₂Cl₆ gas (hereinafter, also referred to as the “HCDS gas”) containing silicon and chlorine (Cl)) in a single molecule of the first gas. That is, the first gas in an undecomposed state is supplied to the surface of the substrate S in the horizontal direction from the side portion (edge) of the substrate S. As a result, the first gas is supplied into the groove, and collides with a wall 700 constituting the groove such that the first gas is decomposed into a precursor. Then, the precursor decomposed as described above adheres to an inner wall of the wall 700 constituting the groove.

In the present step, a distance from the gas supply structure 212 to the substrate S is set according to a time (time duration) that the undecomposed state of the first gas can be maintained. That is, the distance from the gas supply structure 212 to the substrate S is set to a distance corresponding to at least an undecomposed time of the first gas. In other words, the distance by which the first gas reaches the substrate S is set to be a distance at which the precursor can adhere to the inner wall of the wall 700 constituting the groove. Further, the “undecomposed state” of the gas refers to a state which most of the gas supplied thereto is not decomposed. The “undecomposed state” includes not only a state in which an entirety of the gas supplied thereto is not decomposed but also a state in which a predetermined amount of the gas supplied thereto is decomposed and a remainder of the gas supplied thereto is not decomposed. For example, the “predetermined amount” refers to about 1% of the gas supplied thereto.

In the present step, the distance from the gas supply structure 212 to the substrate S is a distance from at least a front end (tip) of the gas supply structure 212 (for example, the front end (tip) of the nozzle 223) to the substrate S. For example, the distance from the gas supply structure 212 to the substrate S may be a distance from the front end of the nozzle 223 to an upstream side edge of the substrate S, may be a distance from the front end of the nozzle 223 to the center of the substrate S, or may be a distance from the front end of the nozzle 223 to a downstream side edge of the substrate S.

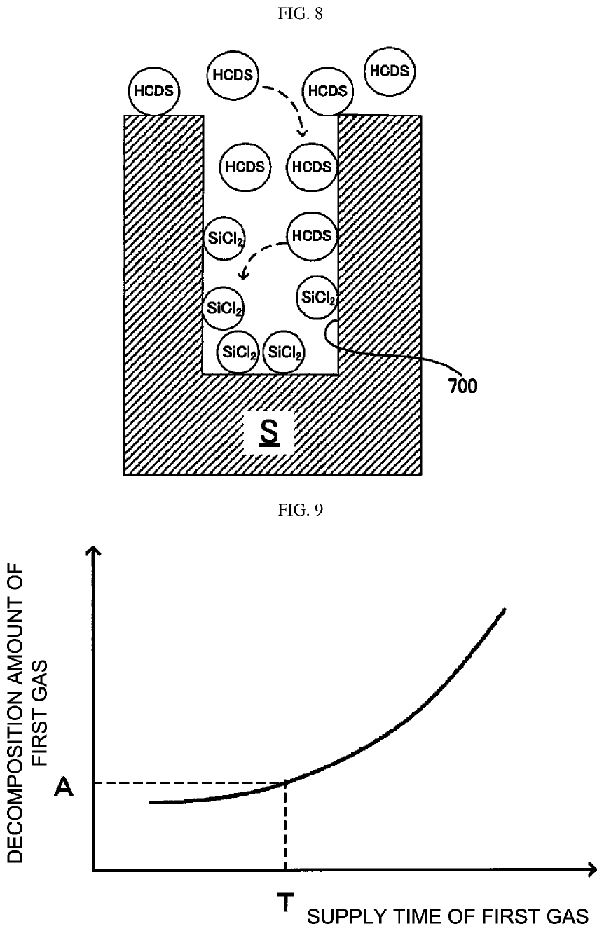

For example, when the HCDS gas is used as the first gas, by supplying the HCDS gas in the undecomposed state (among the HCDS gas supplied into the reaction tube 210) from the side portion (edge) of the substrate S, as shown in FIG. 8, the HCDS gas is supplied into the groove, and collides with the wall 700 constituting the groove. As the HCDS gas collides with the wall 700, by breaking the Si—Si bond, the Si₂Cl₆ (which is the HCDS gas) is decomposed into SiCl₂ (which is the precursor). Since the SiCl₂ is a substance in the process of forming the film, the SiCl₂ may also be referred to as an intermediate substance. Since a molecular size of the SiCl₂ decomposed as described above is smaller than that of the HCDS, the SiCl₂ easily adheres to the wall 700 constituting the groove. That is, by supplying the HCDS gas in the undecomposed state from the side portion (edge) of the substrate S, the HCDS gas is supplied onto the surface of the substrate S in the undecomposed state, and collides with the wall 700 constituting the groove. As a result, the HCDS gas in the undecomposed state is supplied onto the surface of the substrate S, the HCDS gas is decomposed into the SiCl₂ in the groove, and the SiCl₂ decomposed as described above adheres to the groove.

That is, for example, when the HCDS gas is used as the first gas, since the Si—Si bond contains a binding energy as high as to be broken by a collision with the wall 700 constituting the groove, the Si—Si bond is broken by an impact of the collision with the wall 700 of the groove, and is decomposed into the SiCl₂ serving as the precursor. On the other hand, when the first gas is decomposed on an upstream side of the groove, the precursor (SiCl₂) may be generated on the upstream side of the groove, and the film may be formed around the groove and voids may be formed in the groove. As a result, the step coverage performance may be degraded. This is because a deposition rate (film-forming rate) of the precursor decomposed as described above may be high and the precursor decomposed as described above may easily adhere to the wall 700 constituting the groove.

That is, according to the present embodiments, by supplying the HCDS gas in the undecomposed state to the surface of the substrate S and by colliding the HCDS gas with the wall 700 in the groove, it is possible to generate the SiCl₂ whose deposition rate is high. Thereby, the HCDS gas can easily reach the bottom of the groove. As a result, it is possible to form a silicon-containing film whose coverage performance is improved.

Also, a gas whose decomposition amount increases with a lapse of time in a case where a process temperature and a process pressure are substantially constant may be used as the first gas. Then, as shown in FIG. 9, for example, a time T from a start of a supply of the first gas until the first gas reaches the substrate S is set such that the decomposition amount of the first gas is within a predetermined range equal to or less than a predetermined amount A until the time T elapses. The time described above is a time during which the SiCl₂ can adhere to the inner wall of the groove. Further, the process temperature is set be a temperature at which the SiCl₂ can adhere to the inner wall of the groove.

Further, in order to suppress a decomposition rate of the first gas, a total pressure in the reaction tube 210 when supplying the first gas may be set to be a low total pressure of, for example, 100 Pa or less, and the flow velocity of the first gas in the reaction tube 210 may be increased so as to suppress a gas stagnation in the reaction tube 210. For example, when supplying the HCDS gas, the total pressure is set such that the decomposition rate of the HCDS gas is 1% or less. For example, a partial pressure of the SiCl₂ decomposed from the HCDS gas is set to be 0.1 Pa or less. Thereby, it is possible to improve the step coverage performance.

Further, the first gas is supplied at a flow rate for the SiCl₂ capable of being adsorbed (adhering) to the inner wall of the groove. As a result, since the SiCl₂ can be reliably adsorbed on the inner wall of the groove, it is possible to improve the step coverage performance.

In the present step, in a case where an L-shaped nozzle extending in the vertical direction with respect to the substrate S is used as a part of the gas supplier, an inner pressure of the nozzle may increase, and a decomposition of the gas may progress before the gas is supplied to the substrate S. Further, in a case where a configuration in which an exhaust port through which the gas is exhausted in the reaction tube 210 is provided on the lower portion of the reaction tube 210 is used, the gas flows vertically in the reaction tube 210. Thereby, the pressure loss in the gas flow may increase, and the inner pressure of the reaction tube 210 may also increase. Thereby, the decomposition of the gas may progress. Further, in a case where a configuration in which the gas stagnates between the inner wall of the top plate of the reaction tube 210 and the top plate of the substrate support is used, the decomposition of the gas may progress. Further, when supplying the first gas, a gas ejection angle of each of the nozzles arranged in a multistage manner on a side surface of the reaction tube 210 may be oblique with respect to a center axis of the reaction 210.

Further, in order to improve the step coverage performance, the substrate S provided with the groove should be supplied with a sufficient exposure amount (which is an amount obtained by multiplying a supply partial pressure and a supply time) of the source gas. In addition, in a case where an apparatus provided with a configuration in which the gas stagnates in a furnace thereof for a long time, when the source gas is supplied at a high partial pressure, the decomposition of the source gas may progress as compared with a case where the source gas is supplied at a low partial pressure. Therefore, the source gas may be supplied at the low partial pressure so as to improve the step coverage performance. However, when the source gas is supplied at the low partial pressure, in order to secure the sufficient exposure amount, a supply time of the source gas should be lengthened. In other words, there is a trade-off relationship between a productivity and the step coverage performance.

For example, when the HCDS gas is used as the first gas as in the present embodiments, by increasing the temperature of the substrate S, it is possible to desorb reaction by-products such as chlorine (Cl) and hydrogen chloride (HCl) and it is also possible to improve the step coverage performance. However, when the temperature of the substrate S is increased, the decomposition of the gas may progress.

According to the present embodiments, it is possible to shorten the time for the first gas to reach the substrate S. Further, even when the temperature of the substrate S is increased, it is possible to improve the step coverage performance while suppressing the decomposition of the source gas on the surface of the substrate S.

That is, according to the substrate processing apparatus 10 of the present embodiments, even when the source gas is supplied at the high partial pressure, it is possible to shorten the time for the first gas to reach the substrate S, and it is also possible to improve the productivity and the step coverage performance while suppressing the decomposition of the source gas on the surface of the substrate S.

Further, according to the present embodiments, by using the lateral exhaust structure configured to exhaust the gas along the lateral direction of the substrate as the gas exhaust structure 213, it is possible to reduce the pressure loss in the reaction tube 210, and it is also possible to improve a uniformity between the substrates S.

Further, according to the present embodiments, by increasing a width of an opening connected to an exhaust portion of the reaction tube 210, it is possible to suppress the gas stagnation and it is also possible to reduce a swirl of the gas. Thereby, it is possible to suppress the decomposition of the gas on the surface of the substrate S.

Alternatively, the substrates S may be arranged directly below the inner wall of the top plate of the reaction tube 210 by removing the top plate of the substrate support. In such a case, by suppressing the gas stagnation between the top plate of the substrate support and the inside of the reaction tube 210, it is possible to suppress the decomposition rate of the first gas within a predetermined range, and it is also possible to suppress the decomposition of the first gas on the substrate S surface.

Further, the source gas may be supplied in a state where the gas ejection angle of each of nozzles 223 and 224 arranged in the multistage manner on the side surface of the reaction tube 210 is oblique with respect to the center of the reaction tube 210.

<Purge Step: Second Step>

After a predetermined time has elapsed from the start of the supply of the first gas, the valve 254 is closed to stop the supply of the first gas. When stopping the supply of the first gas, the valves 258 and 268 are opened to supply the inert gas serving as the purge gas into the gas supply pipes 255 and 265, and with the valve 282 and APC valve 283 of the exhaust pipe 281 left open, the reaction tube 210 is vacuum-exhausted by the vacuum pump 284. As a result, it is possible to suppress a reaction between the first gas and the second gas in a gas phase existing in the reaction tube 210.

<Second Gas Supply Step: Third Step>

After a predetermined time has elapsed from a start of the purge of the second step, the valves 258 and 268 are closed and the valve 264 is opened so as to supply the second gas into the gas supply pipe 261. The second gas whose flow rate is adjusted by the MFC 263 is supplied into the reaction tube 210 from the gas supply structure 212 via the upstream side gas guide 214. Then, the second gas is exhausted through the space on the substrate S, the downstream side gas guide 215, the gas exhaust structure 213 and the exhaust pipe 281. When supplying the second gas, simultaneously, the valve 268 may be opened so as to supply the inert gas such as the N₂ gas into the gas supply pipe 265. When supplying the second gas, in order to prevent the second gas from entering the gas supply pipe 251, the valve 258 may be opened so as to supply the inert gas into the gas supply pipe 255.

In the present step, for example, the APC valve 283 is appropriately adjusted such that the inner pressure of the reaction tube 210 is set to be a pressure within a range from 1 Pa to 3,990 Pa. For example, a supply flow rate of the second gas controlled (or adjusted) by the MFC 263 is set to be a flow rate within a range from 0.1 slm to 100 slm. For example, a supply time (time duration) of supplying the second gas onto the substrate S is set to be a time within a range from 0.1 second to 1,000 seconds. For example, a flow velocity of supplying the second gas onto the substrate S is set to be a flow velocity within a range from 0.1 m/second to 100 m/second.

In the present step, the second gas is supplied toward the substrate S from the side portion (edge) of the substrate S via the gas supply structure 212. According to the present embodiments, the second gas is different from the first gas. As the second gas, a gas reacting with the first gas is used. For example, the NH₃ gas serving as the nitrogen-containing gas may be used. That is, the second gas is supplied to the surface of the substrate S from the side portion (edge) of the substrate S. Then, the second gas is supplied into the groove and reacts with the precursor adhered to the wall constituting the groove. As a result, the desired film is formed on the substrate S provided with the groove. Specifically, the NH₃ gas reacts with the HCDS gas on the surface of the substrate S, and the NH₃ gas supplied into the groove reacts with the SiCl₂ adhered to the wall constituting the groove to suppress the voids. As a result, for example, it is also possible to form a silicon nitride film (SiN film) whose step coverage performance is improved.

In the present step, when the NH₃ gas is used as the second gas, NH₂ bonds are generated on the film when the HCDS gas and the NH₃ gas react. For example, when the HCDS to be supplied subsequently reacts with the NH₂, chlorine (Cl) and the hydrogen chloride (HCl) will be generated. When chlorine and the HCl remain between the SiCl₂ and the inner wall of the groove, chlorine and HCl prevent the SiCl₂ from adhering to the inner wall of the groove. Therefore, the temperature is set such that the by-products such as the NH₂ generated in the groove of the substrate S can be desorbed and that the decomposition of the HCDS serving as the first gas is not promoted. For example, in a case where the first gas and the second gas are alternately supplied to the substrate, the temperature of the substrate S is set to be a temperature at which a NH termination generated in the groove of the substrate S is desorbed when the first gas and the second gas are alternately supplied to the substrate S without promoting the decomposition of the first gas. Further, the NH₃ gas is supplied from the side portion (edge) of the substrate S during a time in which the HCDS is not decomposed and the SiCl₂ is not generated.

<Purge Step: Fourth Step>

After a predetermined time has elapsed from a start of a supply of the second gas, the valve 264 is closed to stop the supply of the second gas. When stopping the supply of the second gas, the valves 258 and 268 are opened to supply the inert gas serving as the purge gas into the gas supply pipes 255 and 265, and with the valve 282 and APC valve 283 of the exhaust pipe 281 left open, the reaction tube 210 is vacuum-exhausted by the vacuum pump 284. As a result, it is possible to suppress the reaction between the first gas and the second gas in the gas phase existing in the reaction tube 210.

<Performing Predetermined Number of Times>

By performing a cycle (in which the first step through the fourth step described above are sequentially and non-simultaneously performed in this order) a predetermined number of times (N times) (that is, one or more times), a film of a predetermined thickness is formed on the substrate S provided with the groove. According to the present embodiments, for example, a silicon nitride film (SiN film) is formed.

<S110>

Subsequently, a substrate unloading step S110 will be described. In the substrate unloading step S110, the substrate S processed as described above is transferred (unloaded) out of the transfer chamber 217 in the order reverse to that of the substrate loading step S104.

<S15>

Subsequently, a determination step S112 will be described. In the present step, it is determined whether or not the processing of the substrate S described above (that is, the step S104 through S110) has been performed a predetermined number of times. When it is determined that the processing has not been performed the predetermined number of times, the substrate loading step S104 is performed again to process a subsequent substrate S to be processed. When it is determined that the processing has been performed the predetermined number of times, the substrate processing is terminated.

While the present embodiments are described by way of an example in which the horizontal gas flow is formed, the present embodiments are not limited thereto. For example, it is sufficient that a main flow of the gas is generally formed in the horizontal direction. Further, a gas flow diffused in the vertical direction may be formed as long as it does not affect a uniform processing of the plurality of substrates.

Further, in the above, various expressions such as “the same”, “equal”, “similar” and the like are used. However, it goes without saying that the expressions described above mean “substantially the same one”.

<Other Embodiments of Present Disclosure>

While the technique of the present disclosure is described in detail by way of the embodiments described above, the technique of the present disclosure is not limited thereto and may be modified in various ways without departing from the scope thereof.

For example, the embodiments described above are described by way of an example in which, in the film-forming process performed by the substrate processing apparatus 10, the film is formed on the substrate S by using the first gas and the second gas. However, the technique of the present disclosure is not limited thereto. That is, as the process gases used in the film-forming process, other gases may be used to form different films. Further, the technique of the present disclosure may also be applied to film-forming processes using three or more different process gases as long as the three or more different process gases are non-simultaneously supplied (that is, supplied in a non-overlapping manner).

For example, the embodiments described above are described by way of an example in which the film-forming process is performed by the substrate processing apparatus. However, the technique of the present disclosure is not limited thereto. That is, the technique of the present disclosure can be applied not only to the film-forming process of forming the film exemplified in the embodiments described above but also to other film-forming processes of forming another films. For example, the embodiments described above are described by way of an example in which the substrate processing apparatus capable of stacking and processing the plurality of substrates is used. However, the technique of the present disclosure is not limited thereto. For example, the technique of the present disclosure can also be applied to a single wafer type substrate processing apparatus capable of processing a single substrate at a time. Further, one or more constituents of the above-described embodiments may be substituted with one or more constituents of other embodiments, or may be added to other embodiments. Further, a part of one or more constituents of the above-described embodiments may be omitted, or substituted with or added by other constituents.

According to some embodiments of the present disclosure, it is possible to improve the step coverage performance of the film formed on the substrate.

What is claimed is:

1. A processing method comprising:
forming a film on a substrate provided with a concave structure on a surface thereof by performing a cycle a predetermined number of times, wherein the cycle comprises:
(a) supplying a source gas to the substrate from a side of the substrate; and
(b) supplying a reactive gas to the substrate, and
wherein, in (a), by colliding the source gas with an inner wall of the concave structure, the source gas is decomposed to generate an intermediate substance and the intermediate substance adheres to the inner wall of the concave structure, and
wherein, in (b), the intermediate substance adhered to the inner wall of the concave structure reacts with the reactive gas.

2. The processing method of claim 1, wherein the source gas is decomposed by colliding with a wall constituting the concave structure.

3. The processing method of claim 1, wherein the source gas contains a binding energy as high as to be decomposed by colliding with a wall constituting the concave structure.

4. The processing method of claim 1, wherein the source gas contains a silicon-silicon bond, and the silicon-silicon bond is broken by colliding with a wall constituting the concave structure.

5. The processing method of claim 1, wherein a flow velocity of the source gas is set to be equal to a flow velocity for the intermediate substance to adhere to the inner wall of the concave structure.

6. The processing method of claim 1, wherein a time for the source gas to reach the substrate is set to be equal to a time for the intermediate substance to adhere to the inner wall of the concave structure.

7. The processing method of claim 1, wherein a distance for the source gas to reach the substrate is set to be equal to a distance for the intermediate substance to adhere to the inner wall of the concave structure.

8. The processing method of claim 1, wherein the source gas is supplied from a gas supply structure communicating with a space in which the substrate exists, and
wherein a distance from the gas supply structure to the substrate is set based on a time for an undecomposed state of the source gas to be maintained.

9. The processing method of claim 1, wherein the source gas is supplied from a gas supply structure communicating with a space in which the substrate exists, and
wherein a distance from the gas supply structure to the substrate is set to be equal to a distance for the intermediate substance to adhere to the inner wall of the concave structure.

10. The processing method of claim 1, wherein a temperature of the substrate is set to be equal a temperature for the intermediate substance to adhere to the inner wall of the concave structure.

11. The processing method of claim 1, wherein at least two silicon atoms are bonded in a single molecule of the source gas.

12. The processing method of claim 11, wherein the source gas is decomposed by breaking a binding of the at least two silicon atoms.

13. The processing method of claim 1, wherein the source gas comprises a gas containing silicon and chlorine.

14. The processing method of claim 1, wherein the source gas comprises disilicon hexachloride.

15. The processing method of claim 1, wherein the source gas and the reactive gas are alternately supplied to the substrate, and
wherein a temperature of the substrate is set to be a temperature at which a NH termination generated in the concave structure of the substrate is desorbed when the source gas and the reactive gas are alternately supplied to the substrate without promoting a decomposition of the source gas.

16. The processing method of claim 1, wherein a flow velocity of the source gas is set to be within a range from 0.1 m/second to 100 m/second.

17. The processing method of claim 1, wherein a time for the source gas to reach the substrate after being ejected from a nozzle outlet is set to be 0.00001 second or less.

18. The processing method of claim 1, wherein the substrate is heated to a temperature within a range from 100° C. to 1,500° C.

19. The processing method of claim 1, wherein a total pressure when supplying source first gas is set such that a decomposition rate of the source gas is 1% or less or such that a partial pressure of the intermediate substance is 0.1 Pa or less.

20. The processing method of claim 1, wherein, the source gas is supplied in a state where a gas ejection angle of each of nozzles arranged in a multistage manner on a side surface of a reaction tube is oblique with respect to a center of the reaction tube.

21. A method of manufacturing a semiconductor device comprising the processing method of claim 1.

22. A processing apparatus comprising:
a source gas supplier configured to supply a source gas to a substrate provided with a concave structure on a surface thereof from a side of the substrate;
a reactive gas supplier configured to supply a reactive gas to a substrate; and
a controller configured to be capable of controlling the source gas supplier and the reactive gas supplier so as to perform:
forming a film on the substrate by performing a cycle a predetermined number of times, wherein the cycle comprises:
(a) supplying the source gas to the substrate; and
(b) supplying the reactive gas to the substrate, and
wherein, in (a), by colliding the source gas with an inner wall of the concave structure, the source gas is decomposed to generate an intermediate substance and the intermediate substance adheres to the inner wall of the concave structure, and
wherein, in (b), the intermediate substance adhered to the inner wall of the concave structure reacts with the reactive gas.

23. A non-transitory computer-readable recording medium storing a program that causes, by a computer, a substrate processing apparatus to perform:
forming a film on a substrate provided with a concave structure on a surface thereof by performing a cycle a predetermined number of times, wherein the cycle comprises:
(a) supplying a source gas to the substrate from a side of the substrate; and
(b) supplying a reactive gas to the substrate, and
wherein, in (a), by colliding the source gas with an inner wall of the concave structure, the source gas is decomposed to generate an intermediate substance and the intermediate substance adheres to the inner wall of the concave structure, and
wherein, in (b), the intermediate substance adhered to the inner wall of the concave structure reacts with the reactive gas.
